(19) United States
(12) Patent Application Publication
(10) Pub. No.: US 2026/0089960 A1
(43) Pub. Date: Mar. 26, 2026

(54) SEMICONDUCTOR DEVICE AND METHOD OF MANUFACTURING A SEMICONDUCTOR DEVICE

(71) Applicant: SK hynix Inc., Icheon-si Gyeonggi-do (KR)

(72) Inventors: Jeong Sang KANG, Icheon-si Gyeonggi-do (KR); Han I JANG, Icheon-si Gyeonggi-do (KR)

(73) Assignee: SK hynix Inc., Icheon-si Gyeonggi-do (KR)

(21) Appl. No.: 19/055,235

(22) Filed: Feb. 17, 2025

(30) Foreign Application Priority Data
Sep. 25, 2024 (KR) 10-2024-0130158

(51) Int. Cl. H10B 43/35; H10B 41/27; H10B 41/35; H10B 41/41; H10B 43/27; H10B 43/40

(52) U.S. Cl. CPC H10B 43/35; H10B 41/27; H10B 41/35; H10B 41/41; H10B 43/27; H10B 43/40

(57) ABSTRACT

A semiconductor device includes a first source layer, a second source layer positioned over the first source layer, a sub-source layer positioned between the first source layer and the second source layer, a first buffer layer positioned between the first source layer and the sub-source layer, and a second buffer layer positioned between the sub-source layer and the second source layer. The semiconductor device also includes an insulating pattern extending through the second source layer, through the second buffer layer, and into the sub-source layer. The semiconductor device further includes a first conductive pattern extending through the insulating pattern and electrically connected to the sub-source layer and the first source layer, and includes a second conductive pattern positioned in the second source layer and electrically connected to the second source layer.

### CROSS-REFERENCE TO RELATED APPLICATION

The present application claims priority under 35 U.S.C. § 119(a) to Korean Patent Application No. 10-2024-0130158 filed on Sep. 25, 2024, in the Korean Intellectual Property Office, which application is incorporated herein by reference in its entirety.

### BACKGROUND

### 1. Technical Field

The present disclosure relates to an electronic device and a method of manufacturing the electronic device, and more particularly, to a semiconductor device and a method of manufacturing the semiconductor device.

### 2. Related Art

The degree of integration of a semiconductor device is mainly determined by an area occupied by a unit memory cell of the semiconductor device. As the degree of integration of two-dimensional semiconductor devices in which memory cells are formed as single layers on substrates reach a limit, three-dimensional semiconductor devices in which memory cells are stacked on substrates are being proposed. In addition, various structures and manufacturing methods are being developed to improve the operation reliability of semiconductor devices.

### SUMMARY

According to an embodiment of the present disclosure, a semiconductor device may include a first source layer; a second source layer positioned over the first source layer; a sub-source layer positioned between the first source layer and the second source layer; a first buffer layer positioned between the first source layer and the sub-source layer; a second buffer layer positioned between the sub-source layer and the second source layer; an insulating pattern extending through the second source layer, through the second buffer layer, and into the sub-source layer; a first conductive pattern extending through the insulating pattern and electrically connected to the sub-source layer and the first source layer; and a second conductive pattern positioned in the second source layer and electrically connected to the second source layer.

According to an embodiment of the present disclosure, a semiconductor device may include a first electrode layer; a second electrode layer positioned over the first electrode layer; a sub-electrode layer positioned between the first electrode layer and the second electrode layer; a first buffer layer positioned between the first electrode layer and the sub-electrode layer; a second buffer layer positioned between the sub-electrode layer and the second electrode layer; an insulating pattern extending through the second electrode layer, through the second buffer layer, and into the sub-electrode layer; a conductive pattern extending through the insulating pattern and electrically connected to the sub-electrode layer and the first electrode layer; a stack positioned on the second electrode layer; a first contact plug extending through the stack and electrically connected to the conductive pattern; and a second contact plug extending through the stack and electrically connected to the second electrode layer.

According to an embodiment of the present disclosure, a method of manufacturing a semiconductor device may include stacking a first source layer, a first buffer layer, a source sacrificial layer, a second buffer layer, and a second source layer; forming an insulating pattern extending into the source sacrificial layer through the second source layer and the second buffer layer; forming a first conductive pattern extending into the source sacrificial layer and the first source layer through the insulating pattern; and forming a second conductive pattern in the second source layer.

According to an embodiment of the present disclosure, a method of manufacturing a semiconductor device may include forming a capacitor by stacking a first electrode layer, a sub-electrode layer, a second buffer layer, and a second electrode layer; forming an insulating pattern extending through the second electrode layer, through the second buffer layer, and into the sub-electrode layer; forming a conductive pattern extending through the insulating pattern, through the sub-electrode layer, and through the first electrode layer, the conductive pattern electrically connecting with the sub-electrode layer and the first electrode layer; forming a stack on the second electrode layer; forming a first contact plug extending through the stack and electrically connecting to the conductive pattern; and forming a second contact plug extending through the stack and electrically connecting to the second electrode layer.

### BRIEF DESCRIPTION OF THE DRAWINGS

FIGS. 1A and 1B are drawings illustrating a semiconductor device according to an embodiment of the present disclosure.

FIGS. 2A, 2B, 3A, 3B, 4A, 4B, 5A, 5B, 6A, 6B, 7A, 7B, 8A, and 8B are drawings illustrating a method of manufacturing a semiconductor device according to an embodiment of the present disclosure.

### DETAILED DESCRIPTION

Some embodiments of the present disclosure are directed to a semiconductor device, and a method of manufacturing the semiconductor device, having a stable structure and an improved reliability.

Hereinafter, example embodiments according to the technical spirit of the present disclosure are described with reference to the accompanying drawings.

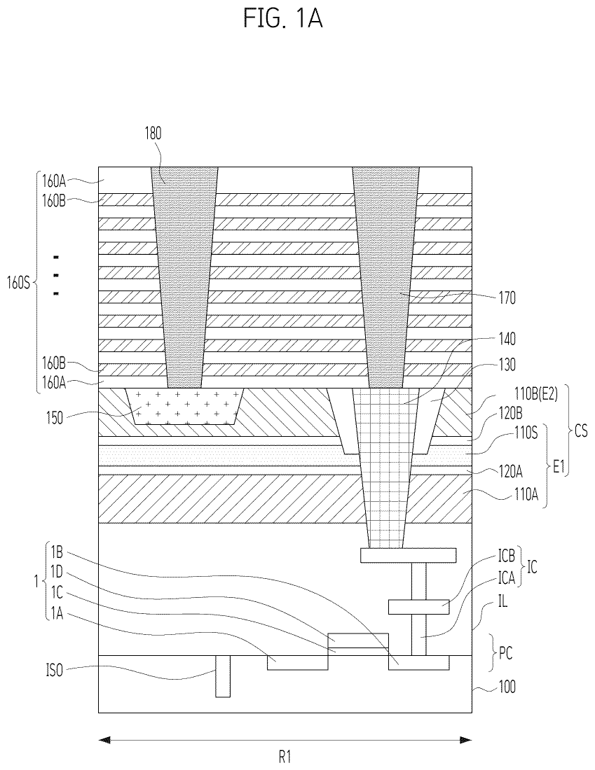

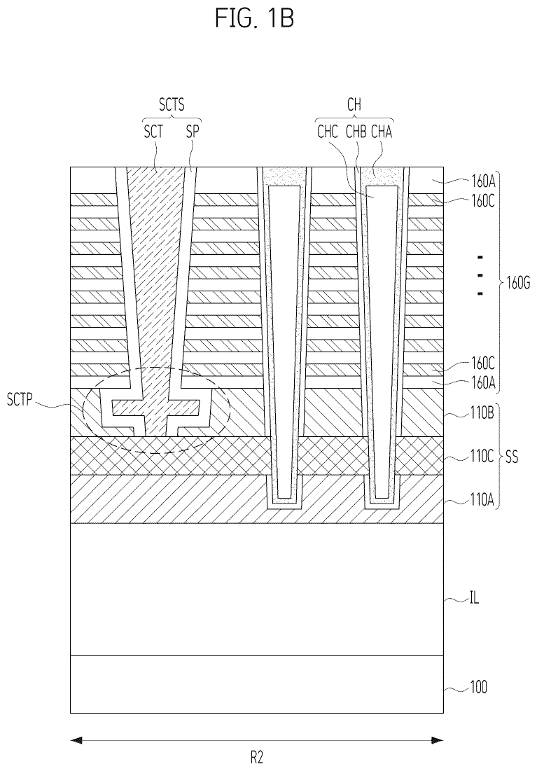

FIGS. 1A and 1B are drawings illustrating a semiconductor device according to an embodiment of the present disclosure.

Referring to FIGS. 1A and 1B, the semiconductor device may include a substrate 100, a peripheral circuit PC, an element isolation layer ISO, an interconnection structure IC, a capacitor CS, an insulating pattern 130, a first conductive pattern 140, a second conductive pattern 150, a stack 160S, a gate structure 160G, a first contact plug 170, a second contact plug 180, a channel structure CH, and a source contact structure SCTS.

The substrate 100 may include a first region R1 and a second region R2. Here, the first region R1 may be a peripheral circuit region, and the second region R2 may be a cell region. The peripheral circuit region may be a region where the peripheral circuit PC is positioned, and the cell region may be a region where memory cells are positioned.

The peripheral circuit PC may be positioned on the substrate 100. For example, the peripheral circuit PC may be positioned in the first region R1. However, the present disclosure is not limited thereto, and the peripheral circuit PC may be positioned in the first region R1 and the second region R2. The peripheral circuit PC may include a transistor 1, a capacitor, and the like. The transistor 1 may include junctions 1A and 1B, a gate electrode 1D, and a gate insulating layer 1C. Here, the gate insulating layer 1C may be positioned between the gate electrode 1D and the substrate 100. The element isolation layer ISO may be positioned in the substrate 100, and an active region of the transistor 1 may be defined by the element isolation layer ISO.

The interconnection structure IC may be positioned on the peripheral circuit PC. The interconnection structure IC may be positioned in an interlayer insulating layer IL. Here, the interlayer insulating layer IL may be positioned on the substrate 100. The interconnection structure IC may include vias ICA and lines ICB.

The interconnection structure IC may be connected to the peripheral circuit PC. For example, at least one of the vias ICA may be connected to the transistor 1. At least one of the vias ICA may interconnect the lines ICB. The lines ICB may interconnect the vias ICA. The interconnection structure IC may include a conductive material, such as tungsten. The interlayer insulating layer IL may include an insulating material, such as an oxide.

The capacitor CS may be positioned over the peripheral circuit PC. For example, the capacitor CS may be positioned in the first region R1. The capacitor CS may include at least one of a first source layer 110A, a second source layer 110B, a sub-source layer 110S, a first buffer layer 120A, or a second buffer layer 120B.

The first source layer 110A may be positioned on the interlayer insulating layer IL. The second source layer 110B may be positioned over the first source layer 110A. The sub-source layer 110S may be positioned between the first source layer 110A and the second source layer 110B. The first buffer layer 120A may be positioned between the first source layer 110A and the sub-source layer 110S. The second buffer layer 120B may be positioned between the sub-source layer 110S and the second source layer 110B. Here, the first source layer 110A, the second source layer 110B, and the sub-source layer 110S may include a conductive material, such as polysilicon. The first buffer layer 120A and the second buffer layer 120B may include an insulating material, such as an oxide.

The first source layer 110A and the sub-source layer 110S may configure a first electrode E1 of the capacitor CS. The second source layer 110B may configure a second electrode E2 of the capacitor CS. The second buffer layer 120B may configure an insulating layer of the capacitor CS. Therefore, according to an embodiment of the present disclosure, the capacitor CS may be configured of the first electrode E1, the second electrode E2, and the insulating layer between the first electrode E1 and the second electrode E2.

In other words, according to an embodiment of the present disclosure, the first source layer 110A, the second source layer 110B, and the sub-source layer 110S, which are not used as a source layer in the first region R1, may be used as electrode layers for configuring the capacitor CS. For example, the first source layer 110A may be used as a first electrode layer, the second source layer 110B may be used as a second electrode layer, and the sub-source layer 110S may be used as a sub-electrode layer. In this case, the first electrode layer and the sub-electrode layer may configure the first electrode E1 of the capacitor CS, and the second electrode layer may configure the second electrode E2 of the capacitor CS.

The insulating pattern 130 may be positioned in the first region R1. The insulating pattern 130 may extend into the sub-source layer 110S through the second source layer 110B and the second buffer layer 120B. The insulating pattern 130 may insulate the first conductive pattern 140 from the second source layer 110B. The insulating pattern 130 may include an insulating material, such as an oxide.

The first conductive pattern 140 may extend through the insulating pattern 130. For example, the first conductive pattern 140 may extend through the insulating pattern 130 and may be electrically connected to the sub-source layer 110S and the first source layer 110A. The first conductive pattern 140 may be part of the first electrode E1 of the capacitor CS by electrically connecting the sub-source layer 110S and the first source layer 110A. The first conductive pattern 140 may be connected to the peripheral circuit PC through the interconnection structure IC. The first conductive pattern 140 may include a conductive material, such as tungsten.

The second conductive pattern 150 may be positioned in the first region R1. The second conductive pattern 150 may be positioned in the second source layer 110B. The second conductive pattern 150 may be electrically connected to the second source layer 110B. The second conductive pattern 150 may prevent the second source layer 110B from being damaged in a process of forming the second contact plug 180. The second conductive pattern 150 may include a conductive material, such as tungsten.

The stack 160S may be positioned in the first region R1. The stack 160S may be positioned on the second source layer 110B. The stack 160S may include first insulating layers 160A and second insulating layers 160B that are alternately stacked. The second insulating layers 160B may be remains without being replaced by conductive layers 160C in a process of manufacturing the semiconductor device. For example, the portions of the second insulating layers 160B in the second region R2 are replaced by the conductive layers 160C, but the remaining portions of the second insulating layers 160B in the first region R1 are left intact. The first insulating layers 160A may include an insulating material, such as an oxide, and the second insulating layers 160B may include an insulating material, such as a nitride.

The first contact plug 170 may extend through the stack 160S and may be connected to the first conductive pattern 140. The second contact plug 180 may extend through the stack 160S and may be connected to the second conductive pattern 150. When a first bias is applied to the first contact plug 170, the first bias may be applied to the first electrode E1 through the first conductive pattern 140. When a second bias different from the first bias is applied to the second contact plug 180, the second bias may be applied to the second electrode E2 through the second conductive pattern 150. Through this, the capacitor CS may be operated or charged. The second contact plug 180 may be electrically connected to the second source layer 110B, used as the second electrode layer E2, through the second conductive pattern 150. The first contact plug 170 and the second contact plug 180 may include a conductive material, such as tungsten.

Although the second conductive pattern 150 is shown in FIG. 1A, the second conductive pattern 150 may be omitted from some embodiments. For example, the second contact plug 180 may extend through the stack 160S and may connect to the second source layer 110B. In this case, the second contact plug 180 may directly apply the second bias to the second electrode E2.

Referring to FIG. 1B, a source structure SS may be positioned in the second region R2. The source structure SS may include a first source layer 110A, a second source layer 110B, and a third source layer 110C. Here, the third source layer 110C may be positioned between the first source layer 110A and the second source layer 110B. The third source layer 110C may be positioned at a level corresponding to the first buffer layer 120A, the sub-source layer 110S, and the second buffer layer 120B. The third source layer 110C may include a conductive material, such as polysilicon.

The capacitor CS of the first region R1 may be positioned at a level corresponding to the source structure SS of the second region R2. In other words, according to an embodiment of the present disclosure, a region used as the source structure SS in the second region R2 might not be used as the source structure SS in the first region R1 and may be used instead as the capacitor CS.

Generally, to additionally form a capacitor in the peripheral circuit PC of a peripheral circuit region, the peripheral circuit region needs to be expanded to accommodate the added capacitor. For an embodiment of the present teachings, however, an improvement in the degree of integration for a semiconductor may be realized because the peripheral circuit region does not need to be expanded to accommodate an additional capacitor. Instead, in a region in which the source structure SS is not used, elements of the unused source structure may be used instead as the capacitor CS. Thus, the degree of integration of a semiconductor device may be improved.

The gate structure 160G may be positioned on the source structure SS. The gate structure 160G of the second region R2 may be positioned at a level corresponding to the stack 160S of the first region R1. The gate structure 160G may include first insulating layers 160A and conductive layers 160C that are alternately stacked. The conductive layers 160C may be gate lines, such as a source selection line, a word line, and a drain selection line. A source selection transistor, a memory cell, or a drain selection transistor may be positioned in a region where the channel structures CH and the conductive layers 160C intersect. For example, at least one source selection transistor, a plurality of memory cells, and at least one drain selection transistor stacked along the channel structure CH may configure one memory string. The conductive layers 160C may include a conductive material, such as tungsten, molybdenum, or polysilicon.

The channel structure CH may extend into the source structure SS through the gate structure 160G. The channel structure CH may include a channel layer CHA and a memory layer CHB. The channel structure CH may further include an insulating core CHC. Here, the memory layer CHB may surround the channel layer CHA. The insulating core CHC may be positioned in the channel layer CHA. The channel layer CHA may be connected to the third source layer 110C.

The source contact structure SCTS may extend into the source structure SS through the gate structure 160G. The source contact structure SCTS may include a bulb portion SCTP. The bulb portion SCTP may be positioned in the second source layer 110B. The bulb portion SCTP of the second region R2 may be positioned at a level corresponding to the second conductive pattern 150 of the first region R1.

The source contact structure SCTS may include a source contact plug SCT and an insulating spacer SP. The source contact plug SCT may be connected to the third source layer 110C of the source structure SS. The insulating spacer SP may surround a sidewall of the source contact plug SCT. The source contact plug SCT may include polysilicon, a metal, or the like. The insulating spacer SP may include an insulating material, such as an oxide, a nitride, or an air gap.

According to the structure described above, the source structure SS may be positioned in the cell region, and the capacitor CS may be positioned in the peripheral circuit region. In other words, in the peripheral circuit region, a region which is not used as the source structure SS may be configured and used as the capacitor CS. Therefore, a degree of integration for a semiconductor device may be improved.

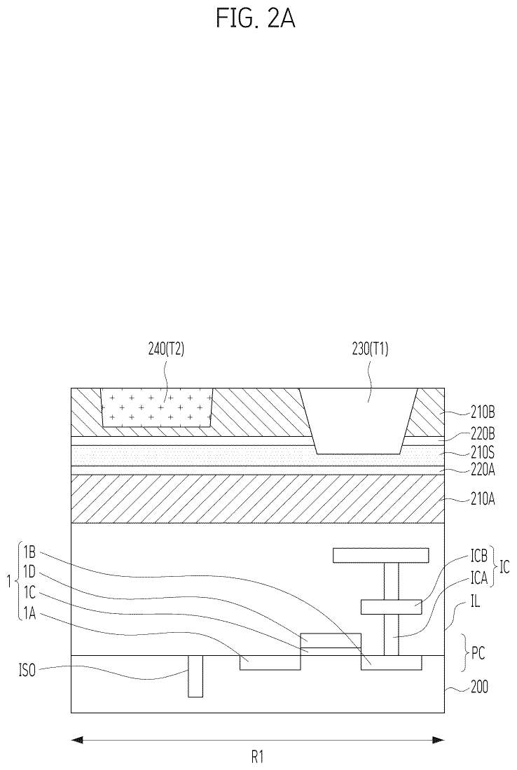

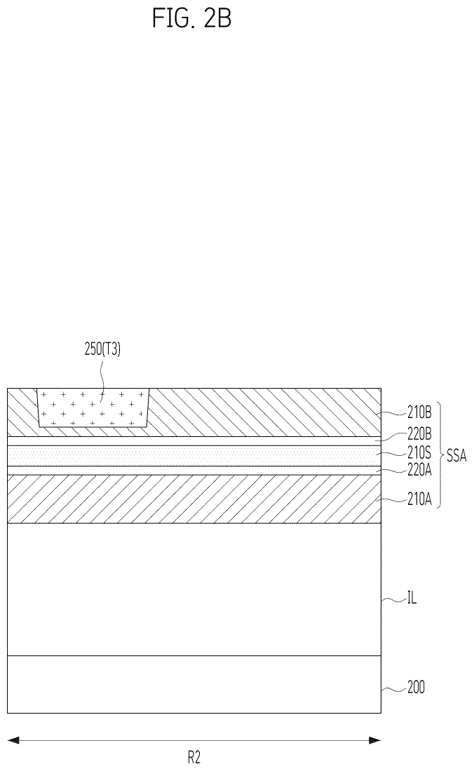

FIGS. 2A to 8B are drawings illustrating a method of manufacturing a semiconductor device according to an embodiment of the present disclosure. Hereinafter, previously described content is not repeated.

Referring to FIGS. 2A and 2B, a peripheral circuit PC may be formed on a substrate 200. Here, the substrate 200 may span a first region R1 and a second region R2. The first region R1 may be a peripheral circuit region, and the second region R2 may be a cell region. The peripheral circuit region may be a region where the peripheral circuit PC is positioned, and the cell region may be a region where memory cells are positioned.

The peripheral circuit PC may include a transistor 1, a capacitor, or the like. The transistor 1 may include junctions 1A and 1B, a gate electrode 1D, and a gate insulating layer 1C. Here, the gate insulating layer 1C may be positioned between the gate electrode 1D and the substrate 200. An element isolation layer ISO may be positioned in the substrate 200, and an active region of the transistor 1 may be defined by the element isolation layer ISO.

Subsequently, an interconnection structure IC may be formed on the peripheral circuit PC. The interconnection structure IC may be positioned in an interlayer insulating layer IL. Here, the interlayer insulating layer IL may be positioned on the substrate 200. The interconnection structure IC may include vias ICA and lines ICB.

The interconnection structure IC may be connected to the peripheral circuit PC. For example, at least one of the vias ICA may be connected to the transistor 1. At least one of the vias ICA may interconnect the lines ICB. The lines ICB may interconnect the vias ICA. The interconnection structure IC may include a conductive material, such as tungsten. The interlayer insulating layer IL may include an insulating material, such as an oxide.

Subsequently, a first source layer 210A, a first buffer layer 220A, a source sacrificial layer 210S, a second buffer layer 220B, and a second source layer 210B may be sequentially stacked. Here, the first source layer 210A, the source sacrificial layer 210S, the second buffer layer 220B, and the second source layer 210B positioned in the first region R1 may configure the capacitor CS.

The first source layer 210A, the first buffer layer 220A, the source sacrificial layer 210S, the second buffer layer 220B, and the second source layer 210B positioned in the second region R2 may configure a preliminary source structure SSA. The first source layer 210A, the second source layer 210B, and the source sacrificial layer 210S may include a conductive material, such as polysilicon. The first buffer layer 220A and the second buffer layer 220B may include an insulating material, such as an oxide.

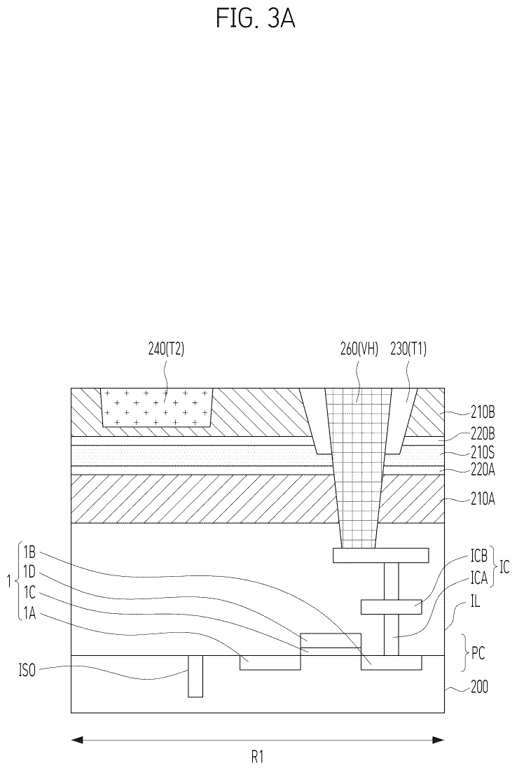

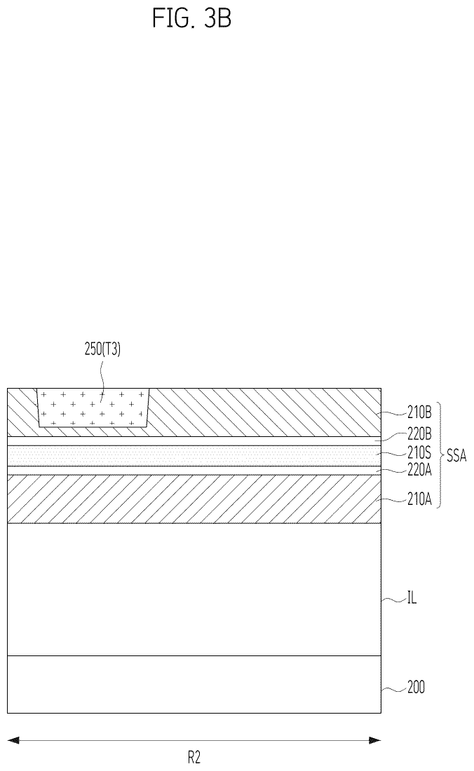

Subsequently, as shown in FIG. 3A, an insulating pattern 230 may be formed in the first region R1. First, a first trench T1 extending into the source sacrificial layer 210S through the second source layer 210B and the second buffer layer 220B may be formed. Subsequently, an insulating pattern 230 may be formed in the first trench T1. Here, the insulating pattern 230 may include an insulating material, such as an oxide.

Subsequently, a second conductive pattern 240 may be formed in the first region R1. First, a second trench T2 may be formed in the second source layer 210B of the first region R1. Subsequently, the second conductive pattern 240 may be formed in the second trench T2. Here, the second conductive pattern 240 may include a conductive material, such as tungsten.

Referring to FIG. 2B, an etch stop pattern 250 may be formed in the second region R2. First, a third trench T3 may be formed in the second source layer 210B of the second region R2. Here, when forming the second trench T2, the third trench T3 may be formed. Subsequently, the etch stop pattern 250 may be formed in the third trench T3. Here, when forming the second conductive pattern 240, the etch stop pattern 250 may be formed. The etch stop pattern 250 may include a conductive material, such as tungsten.

For reference, in this specification, after forming the insulating pattern 230, the second conductive pattern 240 and/or the etch stop pattern 250 are/is formed, a process order is not limited thereto. For example, the insulating pattern 230 may be formed after forming the second conductive pattern 240 and/or the etch stop pattern 250.

Referring to FIGS. 3A and 3B, a first conductive pattern 260 may be formed in the first region R1. First, a hole VH extending through the source sacrificial layer 210S and the first source layer 210A may be formed through the insulating pattern 230. For example, the hole VH may pass through the source sacrificial layer 210S, the first buffer layer 210A, and the first source layer 210A, and may extend into the interlayer insulating layer IL. Here, the hole VH may expose the interconnection structure IC. Subsequently, the first conductive pattern 260 may be formed in the hole VH. Here, the first conductive pattern 260 may include a conductive material, such as tungsten.

The first conductive pattern 260 may be electrically connected to the source sacrificial layer 210S and the first source layer 210A. The first conductive pattern 260 may form part of the first electrode E1 of the capacitor CS by electrically connecting with the source sacrificial layer 210S and the first source layer 210A. For example, the first source layer 210A and the source sacrificial layer 210S may configure the first electrode E1 of the capacitor CS. The second source layer 210B may configure the second electrode E2 of the capacitor CS. The second buffer layer 220B may configure an insulating layer of the capacitor CS. Therefore, according to an embodiment of the present disclosure, the capacitor CS may be configured of the first electrode E1, the second electrode E2, and the insulating layer between the first electrode E1 and the second electrode E2.

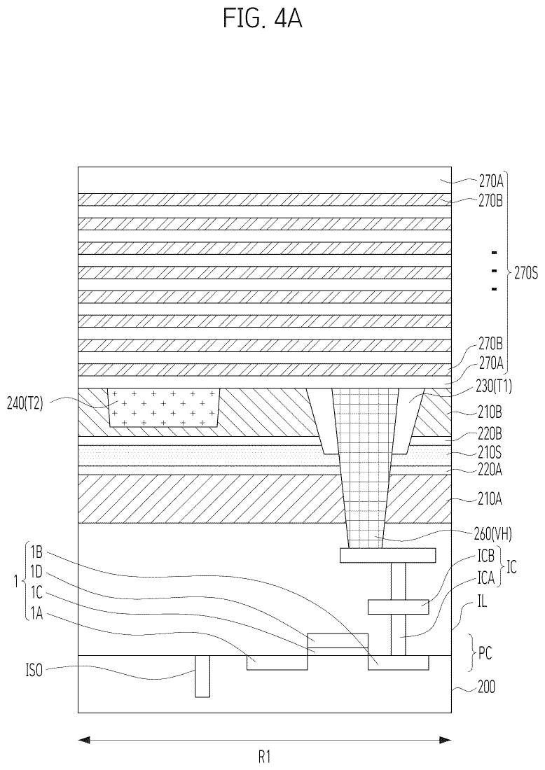

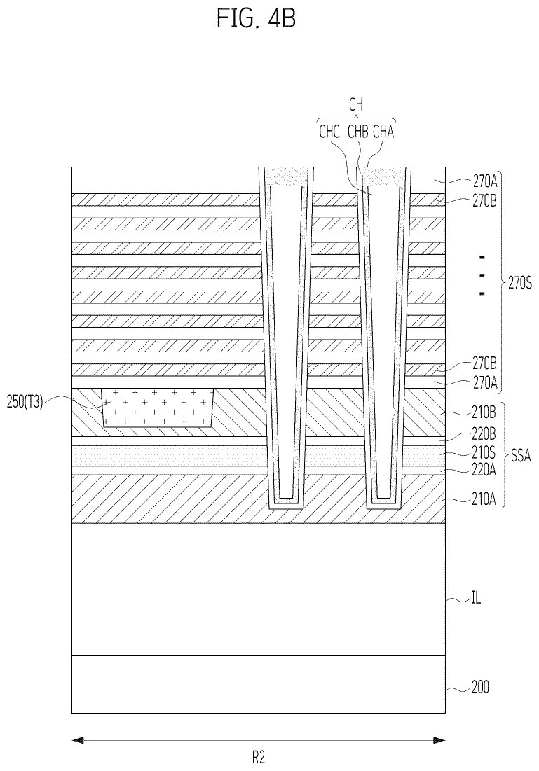

Referring to FIGS. 4A and 4B, first material layers 270A and second material layers 270B may be alternately stacked on the second source layer 210B to form a stack 270S. Here, the first material layers 270A may include an insulating material, such as an oxide, and the second material layers 270B may include a sacrificial material, such as a nitride. Alternatively, the first material layers 270A may include an insulating material, such as an oxide, and the second material layers 270B may include a conductive material, such as tungsten, molybdenum, or polysilicon.

Subsequently, channel structures CH may be formed in the second region R2. For example, the channel structure CH extending through the source sacrificial layer 210S and into the first buffer layer 210A may be formed through the stack 270S, the second source layer 210B, and the second buffer layer 220B. Here, the channel structure CH may include a channel layer CHA and a memory layer CHB surrounding the channel layer CHA. The channel structure CH may further include an insulating core CHC in the channel layer CHA.

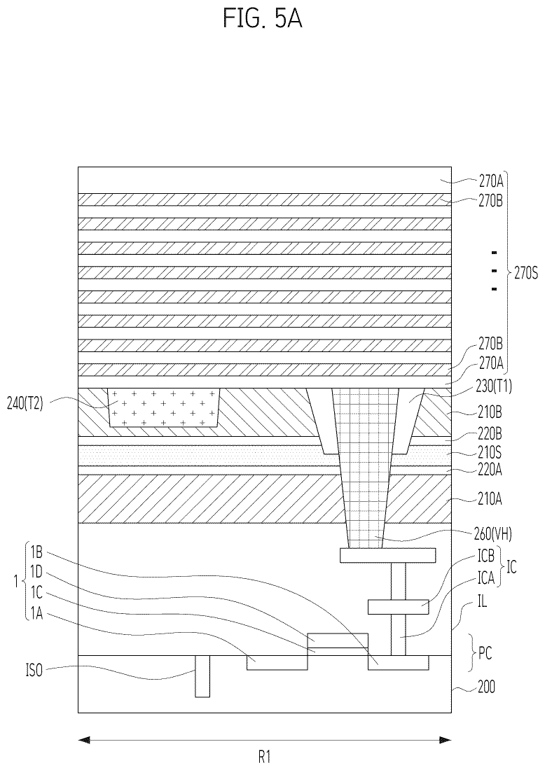

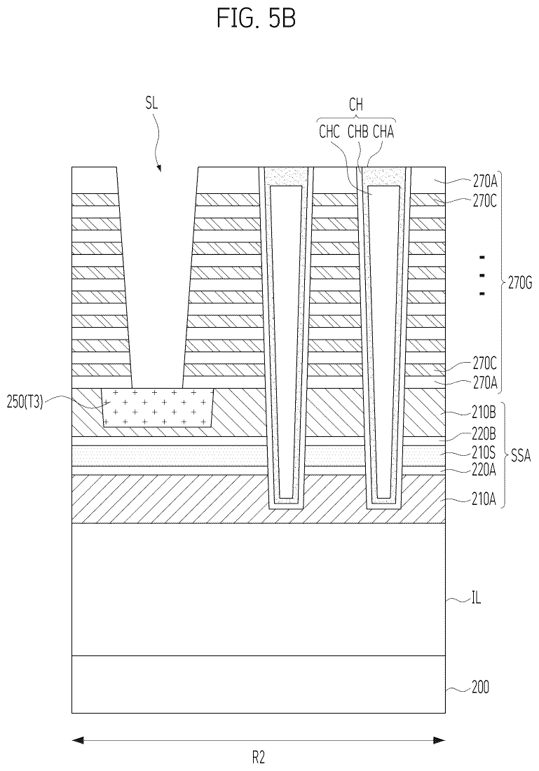

Referring to FIGS. 5A and 5B, a slit SL may be formed in the second region R2. For example, the slit SL may extend through the stack 270S to expose the etch stop pattern 250. Here, the etch stop pattern 250 may prevent or reduce damage to the preliminary source structure SSA in a process of forming the slit SL. For example, the etch stop pattern 250 may prevent damage to the second source layer 210B due to excessive etching in the process of forming the slit SL.

Subsequently, the second material layers 270B may be replaced with third material layers 270C through the slit SL. For example, after the second material layers 270B are removed through the slit SL, the third material layers 270C may be formed. Here, the third material layers 270C may include a conductive material, such as tungsten, molybdenum, or polysilicon.

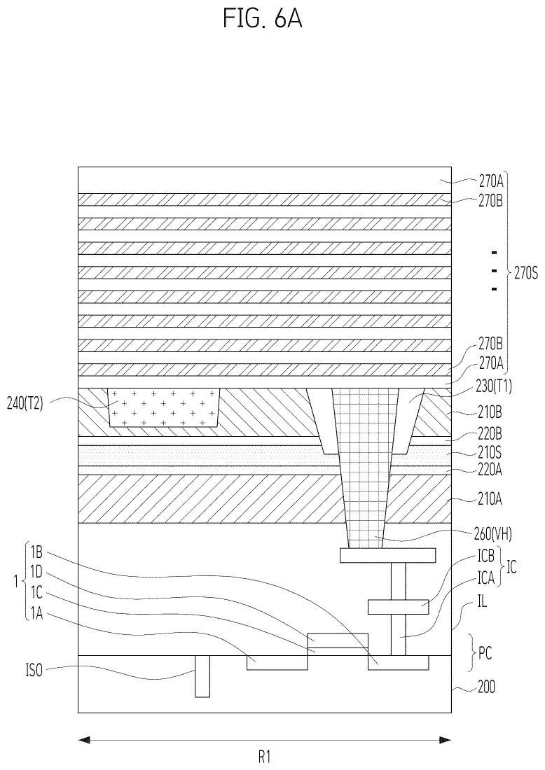

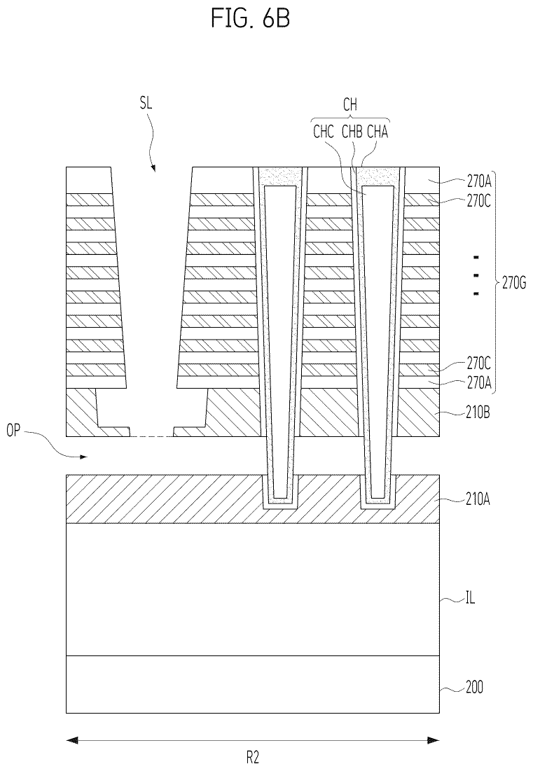

Referring to FIGS. 6A and 6B, the etch stop pattern 250 may be removed through the slit SL. Subsequently, the slit SL may be extended so that the second buffer layer 220B is exposed. Subsequently, the source sacrificial layer 210S may be removed through the slit SL to form an opening OP. Subsequently, the memory layer CHB may be partially etched through the opening OP to expose the channel layer CHA. When the memory layer CHB is partially etched and removed through the opening OP, the second buffer layer 220B and the first buffer layer 210B may be removed. Through this, the opening OP may be expanded.

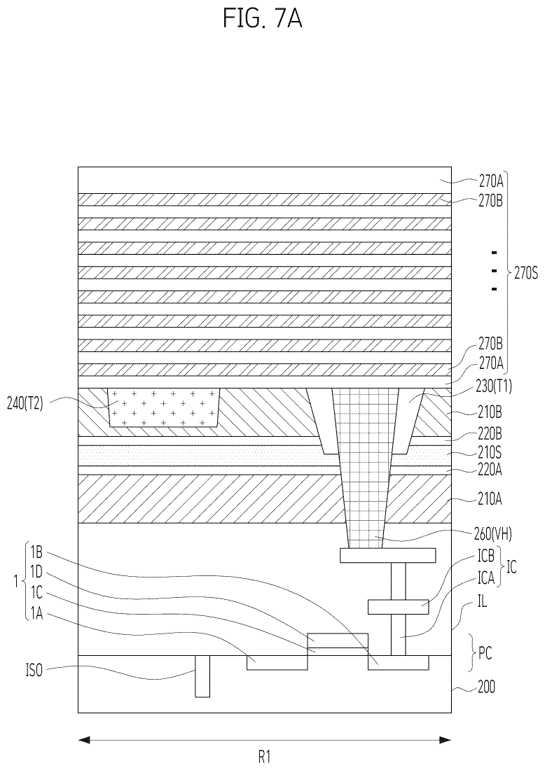

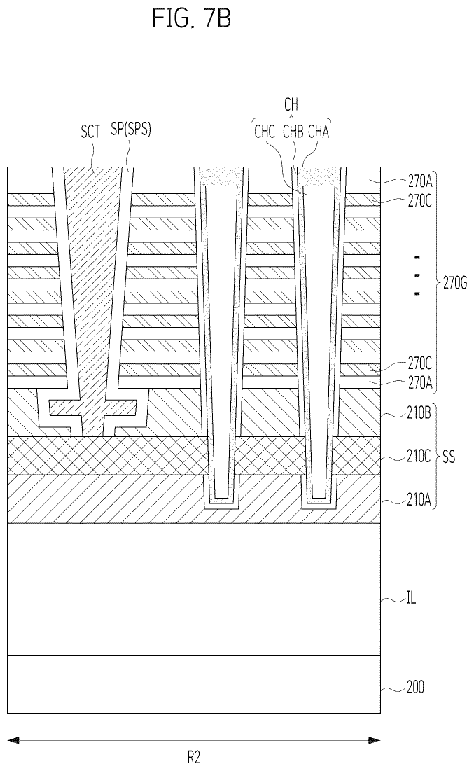

Referring to FIGS. 7A and 7B, a third source layer 210C may be formed in the opening OP. Accordingly, the source structure SS including the first source layer 210A, the second source layer 210B, and the third source layer 210C may be formed. Here, the third source layer 210C may be connected to the channel layer CHA of the channel structure CH. The third source layer 210C may include a conductive material, such as polysilicon.

Subsequently, an insulating spacer SP may be formed in the slit SL. First, a preliminary insulating spacer SPS may be formed in the slit SL. For example, the preliminary insulating spacer SPS may be conformally formed in the slit SL. Subsequently, a lower surface of the preliminary insulating spacer SPS may be etched to expose the third source layer 210C. Here, the insulating spacer SP may include an insulating material, such as an oxide, a nitride, or an air gap.

Subsequently, a source contact plug SCT may be formed in the slit SL. The source contact plug SCT may be connected to the third source layer 210C of the source structure SS. The source contact plug SCT may include polysilicon, a metal, or the like.

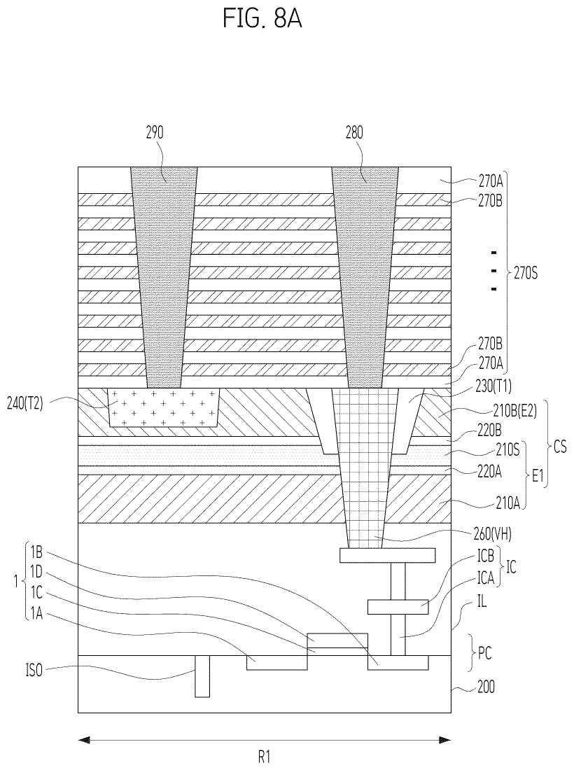

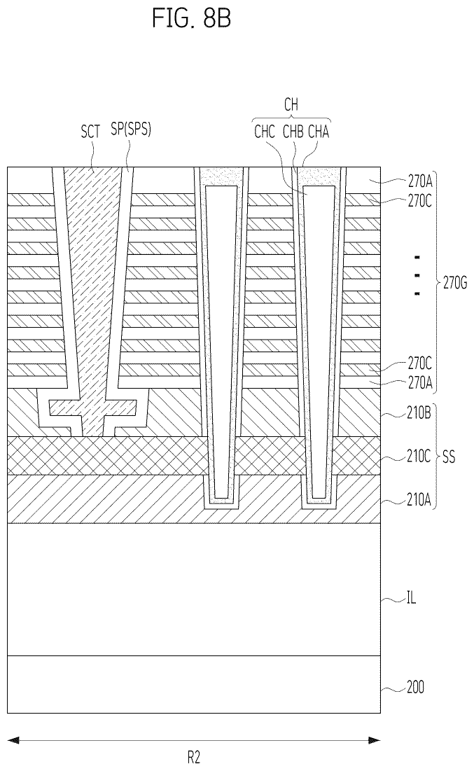

Referring to FIGS. 8A and 8B, a first contact plug 280 may be formed in the first region R1. For example, the first contact plug 280 may extend through the stack 270S and connect to the first conductive pattern 260. The first contact plug 280 may include a conductive material, such as tungsten.

A second contact plug 290 may be formed in the first region R1. For example, the second contact plug 290 may extend through the stack 270S and connect to the second conductive pattern 240. When forming the first contact plug 280, the second contact plug 290 may be formed. Here, the second contact plug 290 may include a conductive material, such as tungsten.

The first and second conductive patterns 260 and 240 may prevent or reduce damage to the capacitor CS in a process of forming the first and second contact plugs 280 and 290. For example, the first and second conductive patterns 260 and 240 may be used as an etch stop layer in a process of forming a hole for forming the first and second contact plugs 280 and 290.

Although an insulating spacer surrounding the first and second contact plugs 280 and 290 is not shown in this drawing, an insulating spacer surrounding the first and second contact plugs 280 and 290 may exist for some embodiments. For example, when the first material layers 270A include an insulating material, such as an oxide, and the second material layers 270B include a conductive material, such as tungsten, molybdenum, or polysilicon, by forming the insulating spacer before forming the first and second contact plugs 280 and 290, electrical connection between the first and second contact plugs 280 and 290 and the second material layers 270B may be prevented.

According to an embodiment of the present disclosure, the first source layer 210A, the second source layer 210B, and the source sacrificial layer 210S, which are not used as a source layer of the source structure SS in the first region R1, may be used as an electrode layer for configuring the capacitor CS. For example, the first source layer 210A may be used as a first electrode layer, the second source layer 210B may be used as a second electrode layer, and the source sacrificial layer 210S may be used as a sub-electrode layer. In this case, the first electrode layer and the sub-electrode layer may configure the first electrode E1 of the capacitor CS, and the second electrode layer may configure the second electrode E2 of the capacitor CS.

Although the second conductive pattern 240 is shown in this drawing, the second conductive pattern 240 may be omitted for some embodiments. For example, the second contact plug 290 may extend through the stack 270S and may connect to the second source layer 210B.

According to the manufacturing method described above, when forming the second conductive pattern 240 in the peripheral circuit region, an etch stop pattern 250 may be formed in the cell region. Therefore, by unifying the process, the manufacturing time and cost of the semiconductor device may be reduced for some embodiments.

In addition, the first source layer 210A, the second source layer 210B, and the source sacrificial layer 210S, which are not used as the source layer of the source structure SS in the first region R1, may be used as electrode layers of the capacitor CS. In other words, source structure components not used as the source structure SS in the peripheral circuit region may be used instead to form the capacitor CS. Because the peripheral circuit region might not need to be expanded to form the capacitor CS, the degree of integration of the semiconductor device may be improved.

Although some embodiments according to the technical spirit of the present disclosure have been described with reference to the accompanying drawings, the present disclosure is not limited to the above-described embodiments and other embodiments are possible. In the scope of the technical spirit of the present disclosure described in the claims, various forms of substitution, modification, and change of the embodiments will be possible by those skilled in the art to which the present disclosure belongs, and these also belong to the scope of the present disclosure.

What is claimed is:

1. A semiconductor device comprising:
a first source layer;
a second source layer positioned over the first source layer;
a sub-source layer positioned between the first source layer and the second source layer;
a first buffer layer positioned between the first source layer and the sub-source layer;
a second buffer layer positioned between the sub-source layer and the second source layer;
an insulating pattern extending through the second source layer, through the second buffer layer, and into the sub-source layer;
a first conductive pattern extending through the insulating pattern and electrically connected to the sub-source layer and the first source layer; and
a second conductive pattern positioned in the second source layer and electrically connected to the second source layer.

2. The semiconductor device of claim 1, wherein the first source layer, the sub-source layer, the second buffer layer, and the second source layer form a capacitor.

3. The semiconductor device of claim 2, wherein the capacitor comprises:
a first electrode including the first source layer and the sub-source layer; and
a second electrode including the second source layer.

4. The semiconductor device of claim 1, further comprising:
a stack positioned on the second source layer;
a first contact plug extending through the stack and electrically connected to the first conductive pattern; and
a second contact plug extending through the stack and electrically connected to the second conductive pattern.

5. The semiconductor device of claim 4, further comprising:
a source structure including the first source layer, the second source layer, and a third source layer positioned between the first source layer and the second source layer;
a gate structure positioned on the source structure and positioned at a level corresponding to the stack; and
a source contact structure extending through the gate structure and into the source structure.

6. The semiconductor device of claim 5, wherein the source contact structure includes a bulb portion positioned in the second source layer, and
the bulb portion is positioned at a level corresponding to the second conductive pattern.

7. The semiconductor device of claim 5, further comprising:
a channel structure extending through the gate structure and into the source structure.

8. The semiconductor device of claim 7, wherein the channel structure includes a channel layer and a memory layer surrounding the channel layer.

9. The semiconductor device of claim 8, wherein the channel layer is connected to the third source layer.

10. The semiconductor device of claim 1, further comprising:
a peripheral circuit; and
an interconnection structure positioned on the peripheral circuit, the interconnection structure electrically connecting the peripheral circuit to the first conductive pattern.

11. A semiconductor device comprising:
a first electrode layer;
a second electrode layer positioned over the first electrode layer;
a sub-electrode layer positioned between the first electrode layer and the second electrode layer;
a first buffer layer positioned between the first electrode layer and the sub-electrode layer;
a second buffer layer positioned between the sub-electrode layer and the second electrode layer;
an insulating pattern extending through the second electrode layer, through the second buffer layer, and into the sub-electrode layer;
a conductive pattern extending through the insulating pattern and electrically connected to the sub-electrode layer and the first electrode layer;
a stack positioned on the second electrode layer;
a first contact plug extending through the stack and electrically connected to the conductive pattern; and
a second contact plug extending through the stack and electrically connected to the second electrode layer.

12. The semiconductor device of claim 11, wherein the first electrode layer, the sub-electrode layer, the second buffer layer, and the second electrode layer form a capacitor.

13. The semiconductor device of claim 12, wherein the capacitor comprises:
a first electrode including the first electrode layer and the sub-electrode layer; and
a second electrode including the second electrode layer.

14. The semiconductor device of claim 11, further comprising:
a peripheral circuit; and
an interconnection structure positioned on the peripheral circuit, the interconnection structure electrically connecting the peripheral circuit to the conductive pattern.
